(19) United States
(12) Patent Application Publication
(10) Pub. No.: US 2008/0174973 A1
(43) Pub. Date: Jul. 24, 2008

(54) Printed circuit board assembly, enclosure of information technology equipment, and information technology equipment

(75) Inventors: Yoshiro Tanaka, Kawasaki (JP); Toshiyuki Homma, Kawasaki (JP); Hideaki Kamikakoi, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, KAWASAKI (JP)

(21) Appl. No.: 11/984,106

(22) Filed: Nov. 13, 2007

(30) Foreign Application Priority Data
Jan. 18, 2007 (JP) 2007-009392

(51) Int. Cl. H05K 1/14

(52) U.S. Cl. 361/736

(57) ABSTRACT

A printed circuit board assembly is configured and arranged so that memory modules are mounted thereto. At least two connectors are mounted on a printed circuit board. The connectors are configured so that the memory modules are connected thereto. An electromagnetic wave absorption sheet is provided to at least one of the connectors. The electromagnetic wave absorption sheet is attached so as to cover a side surface of the one connector facing a side surface of the other connector.

### BACKGROUND OF THE INVENTION

1. Field of the Invention

The present invention relates to information technology equipment and, more particularly, to information technology equipment such as a notebook-type personal computer provided with an opening part for replacing memory modules.

2. Description of the Related Art

In recent years, it has become indispensable to take countermeasures for electromagnetic interference (EMI) and electrostatic discharge (ESD) on information technology equipment such as a desktop-type personal computer (desktop PC), a notebook-type personal computer (note PC), a printer, a facsimile machine, etc. In EMC, regulation has been tightened with respect to EMI, especially, and each country enforces its own regulation. Manufacturers of information technology equipment cannot sell or export products unless they clear the limits specified by the standard regarding EMI regulation. As a standard regarding EMI regulation, there are, for example, the agreement of VCCI in Japan and the FCC rules in the United States of America.

As an international standard used as the basis of the standard regarding EMI regulation, there is the standard established by the International Special Committee on Radio Interference (CISPR). It is a present situation that each country establishes a standard based on the CISPR standard. Thus, if the CISPR standard can be cleared, the standard of each country can be cleared approximately.

Generally, in a note PC which is one of information technology equipment, a metal plate or a metal sheet is applied or metal plating is applied onto a backside of an enclosure so that electromagnetic waves do not leak from an interior of the enclosure. If an entire surface of the enclosure is covered by a metal, the enclosure can be constructed so that electromagnetic waves do not leak outside. However, it is difficult to completely cover the entire surface of the enclosure. That is, for example, an opening is formed on the enclosure at a portion where a connector for connection to an external device, and electromagnetic waves may leak through the opening.

Thus, it is suggested to minimize an amount of leakage of electromagnetic waves, as measures for EMI, by attaching a metal-made or metal-plated cover to an opening part and electrically connecting a metal portion of the cover to a ground potential portion of an enclosure (refer to Patent Document 1).

Patent Document 1: Japanese Laid-Open Patent Application No. 2000-151132

In a personal computer or the like, it has become general to provide a memory module cover g to an enclosure so as to incorporate an extended memory module to a printed circuit board inside the enclosure. Although the opening is closed by a metal-made or metal-plated cover, it is difficult to cover a portion between the edge of the cover and the opening of the enclosure. Thus, electromagnetic waves may leak through such a portion, which may prevent the limits specified by EMI standard from being cleared.

Especially, in a note PC, there are many cases where a so-called butterfly-type connection structure which enables to connect two memory modules facing each other. In the butterfly-type connection structure, signal lines to the memories extend between the two memories. Since transmission and reception of signals are performed frequently through the signal lines, the signal lines are source of generation of electronic waves.

Therefore, when the butterfly-type connection structure is adopted as a memory module connection structure which enables extension and replacement of memory modules, an opening part of an enclosure is located in the vicinity of the butterfly-type connection structure. Thereby, an amount of leakage of electromagnetic waves leaking through a periphery of the opening part becomes extremely large, which may cause a problem in that the limits specified by EMI standard cannot be cleared.

Moreover, when the butterfly-type connection structure is adopted as a memory module connection structure, it is possible that an unnecessary electromagnetic wave is generated at terminal portions of the two connectors that are located parallel to each other so as to connect the two memories. For example, if a memory module is connected to one of the connectors and a memory module is not connected to the other one of the connectors as a connector for memory extension, a voltage fluctuation during operations of the memory connected to the one of the connectors appear at the terminals of the other one of the connectors through the connectors. Since the terminals of the other one of the connectors are not connected to a memory and they are open terminals, the voltage fluctuation stays at the terminals, which generates electromagnetic waves. The thus-generated electromagnetic waves are a part of electromagnetic waves leaking through the opening part for memory.

### SUMMARY OF THE INVENTION

It is a general object of the present invention to provide an improved and useful information technology equipment in which the above-mentioned problems are eliminated.

A more specific object of the present invention is to provide a printed circuit board assembly, an enclosure of information technology equipment and an information technology equipment, which can reduce an amount of electromagnetic waves leaking through an opening part provided for memory module replacement.

In order to achieve the above-mentioned problems, there is provided according to one aspect of the present invention a printed circuit board assembly configured and arranged so that memory modules are mounted thereto, the printed circuit board assembly comprising: a printed circuit board; at least two connectors mounted on the printed circuit board, the connectors being configured so that the memory modules are connected thereto; an electromagnetic wave absorption sheet provided to at least one of the connectors, wherein the electromagnetic wave absorption sheet is attached so as to cover a side surface of the one connector facing a side surface of the other connector.

Additionally, there is provided according to another aspect of the present invention an enclosure of information technology equipment configured so that a printed circuit assembly is incorporated therein, the printed circuit assembly being configured so that memory modules are mounted opposite and parallel to each other, the enclosure of information technology equipment comprising: an opening part provided on an enclosure wall at a position opposite to said memory modules; a cover for closing the opening part; and a metal plate provided to cover an inner surface of the enclosure wall on which said opening part is provided, the metal plate being at a ground potential, wherein a conductive material is provided on an inner surface of the cover, and a portion of the metal plate is formed as a protruding part so that the protruding part is in contact with the conductive material in a vicinity of the opening part.

Further, there is provided according to another aspect of the present invention an information technology equipment having a changeable memory capacity, comprising: the above-mentioned printed circuit board assembly; and the above-mentioned enclosure of information technology equipment, wherein the printed circuit board assembly is incorporated into the enclosure of information technology equipment.

According to the above-mentioned invention, there is no need to cover an entire surface of the memory module cover and the electromagnetic wave absorption sheet may cover only the side surface of the connector. Accordingly, electromagnetic waves can be shielded efficiently while reducing an amount of use of the expensive electromagnetic wave absorption sheet.

Other objects features and advantages of the present invention will become more apparent from the following detailed description when read in conjunction with the accompanying drawings.

### BRIEF DESCRIPTION OF THE DRAWINGS

FIG. 1 is an illustrative perspective view of a note PC as an example of an information technology equipment to which the present invention is applied;

FIG. 2 is an illustrative plan view of a housing of the note PC shown in FIG. 1 viewed from a bottom side;

FIG. 3 is an illustration showing a positional relationship between memory modules, the enclosure and a memory module cover;

FIG. 4 is an illustration showing a state where a memory module cover is attached to an opening part;

FIG. 5 is an illustrative perspective cross-sectional view of an enclosure of a note PC as an example of an information technology equipment according to a first embodiment of the present invention;

FIG. 6 is an illustrative plan view of the enclosure shown in FIG. 5 viewed from a bottom side;

FIG. 7 is an illustrative cross-sectional view showing a state where a memory module cover is attached to an opening part of the enclosure;

FIG. 8 is an illustrative perspective cross-sectional view of an enclosure of a note PC according to a second embodiment of the present invention;

FIG. 9 is an illustrative plan view of the enclosure shown in FIG. 8 viewed from a bottom side; and

FIG. 10 is an illustrative cross-sectional view showing a state where a memory module cover is attached to an opening part of the enclosure.

### DETAILED DESCRIPTION OF THE PREFERRED EMBODIMENTS

A description will now be given, with reference to the drawings, of embodiments according to the present invention.

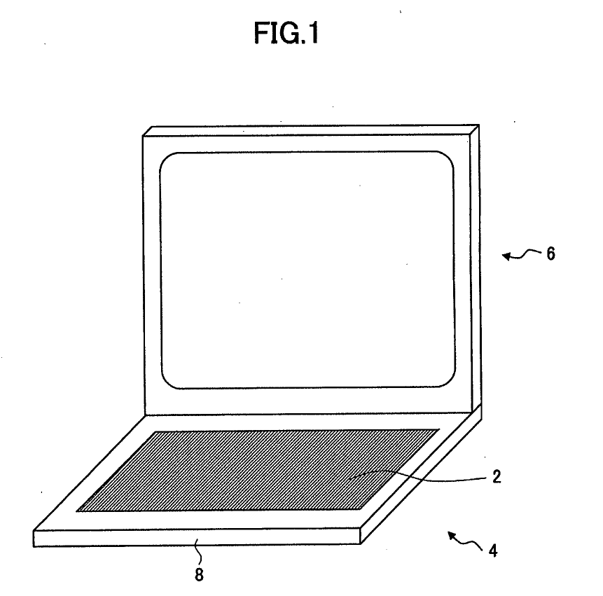

FIG. 1 is an illustrative perspective view of a note PC as an example of an information technology equipment to which the present invention is applied. The note PC has a main part 4 in which a keyboard 2 is arranged and a display part 6 which is rotatable relative to the main part 4. The main part 4 has an enclosure 8, and the keyboard 2 is arranged on an upper surface of the enclosure 8. Accommodated in the enclosure 8 are a circuit board having a CPU and a memory module mounted thereon, a storage device such as a hard disk drive, a module for communication with external devices, connectors, etc.

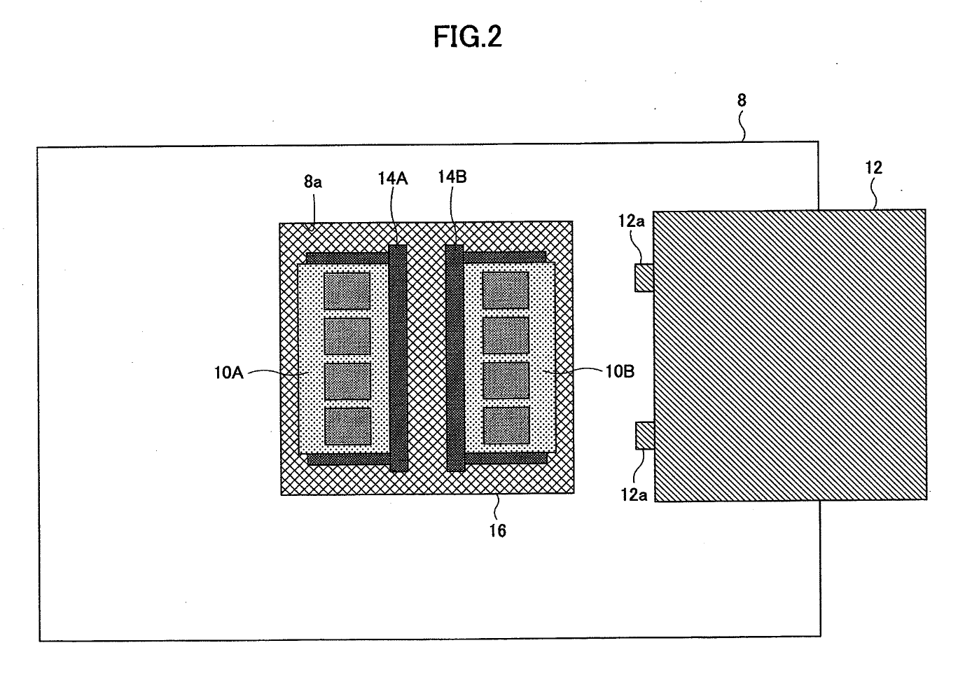

Consideration is given of a case where two memory modules are mounted in the note PC shown in FIG. 1. FIG. 2 is an illustrative plan view of the enclosure 8 of the note PC shown in FIG. 1 viewed from a bottom side (a side opposite to the keyboard 2). On the bottom side of the enclosure 8, an opening part 8a is provided at a portion corresponding to the memory modules 10A and 10B so as to make the memory modules 10A and 10B replaceable. A memory module cover 12, which is removable, is attached to the opening part 8a. In FIG. 2, the memory module cover 12 is shown in a state where it is removed from the opening part 8a. Accordingly, in FIG. 2, a state is shown where the memory modules 10A and 10B inside the enclosure 8 are seen through the opening part 8a on the bottom side of the enclosure 8.

The two memory modules 10A and 10B have the same outer configuration of generally rectangular shape and have the same size. Connection terminals are arranged along one side (longer side) of the rectangular shape. Two connectors 14A and 14B are mounted on a printed circuit board 16, which is a circuit board accommodated in the enclosure 8. The connectors 14A and 14B serve as memory slots to which the memory modules 10A and 10B are connected. Circuit parts and connectors are mounted on the printed circuit board 16 so as to form a printed circuit board assembly, which is incorporated in the enclosure 8.

The two connectors 14A and 14B are arranged in parallel in a state where connection parts face opposite to each other. The memory module 10A is inserted into the left side connector 14A from a left side, and the memory module 10B is inserted into the right side connector 14B from a right side. As mentioned above, a so-called butterfly-type connection structure is adopted as the connection structure of the memory modules 10A and 10B.

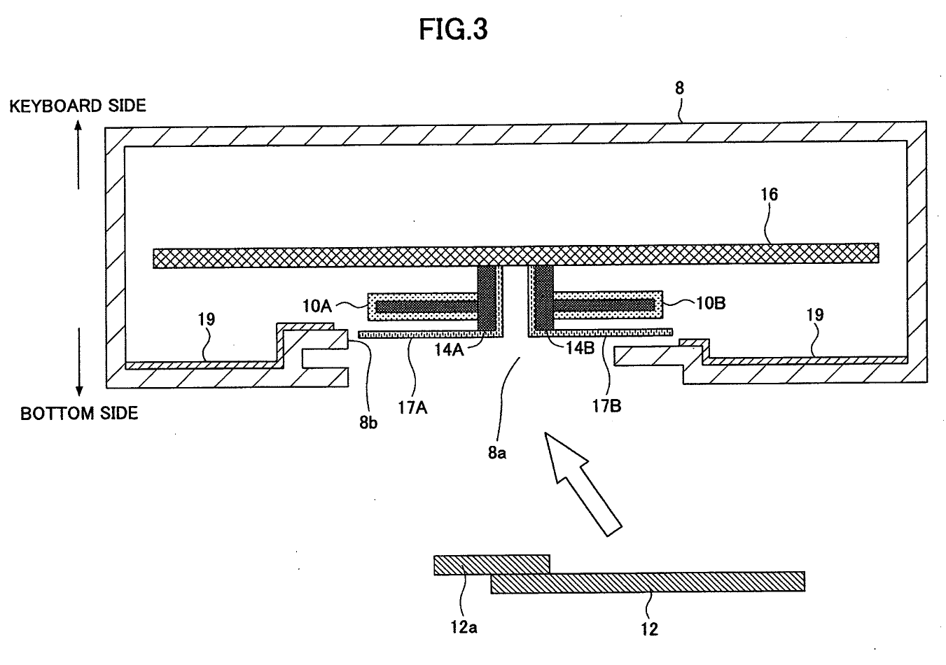

FIG. 3 is an illustration showing a positional relationship between the memory modules 10A and 10B, the enclosure 8, and the memory module cover 12, in which a state where the inside of the enclosure 8 is seen from a side is shown. The connectors 14A and 14B are mounted on the printed circuit board 16 accommodated in the enclosure 8, and the memory modules 10A and 10B are connected to the connectors 14A and 14B, respectively.

Moreover, an insulation film 17A is provided so as to cover the side of the connector 14A and the memory module 10A. The insulation film 17A is applied to the side surface of the connector 14A by a pressure sensitive adhesive, and is bent by 90 degrees and arranged to cover connector pins of the connector 14A. Similarly, an insulation film 17B is provided to cover the side surface of the connector 14B and the memory module 10B.

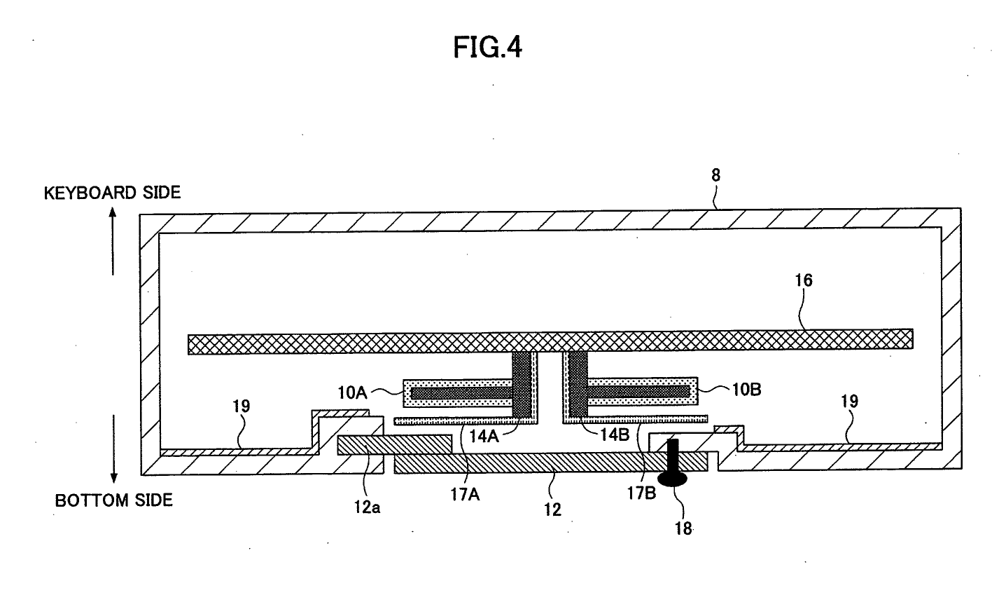

The opening 8a is formed in a bottom side enclosure wall of the enclosure 8 under the memory modules 10A and 10B, and the memory module cover 12 is attached to close the opening part 8a. The memory module cover 12 has protruding strips 12a on one side thereof so that the memory module cover 12 can be attached to the opening part 8a in a state where the protruding strips 12a are inserted into engaging parts 8b provided on one side of the opening part 8a of the enclosure 8. FIG. 4 is an illustration showing a state where the memory module cover 12 is attached to the opening part 8a. The memory module cover 12 is moved in a direction indicated an arrow in FIG. 2 and FIG. 3 while inserting the protruding parts 12a into the engaging parts 8b, and fixed by screws 18 in a state where the memory module cover 12 covers the opening part 8a.

It should be noted that a metal plate 19 such as an aluminum plate or the like is provided on an inner surface of the enclosure 8, especially, a back surface side where the opening part 8a is provided, so as to cover the entire inner surface of the enclosure wall on the bottom side. The metal plate 19 reinforces the enclosure 8 and also serves as an electromagnetic wave shielding material.

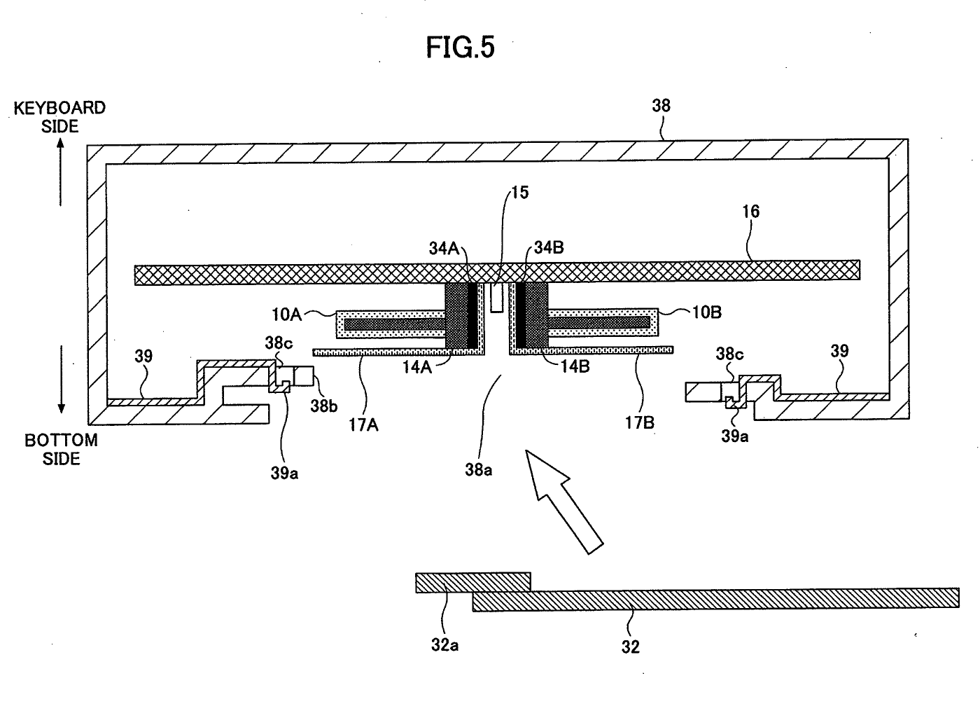

A description will now be given, with reference to FIG. 5 through FIG. 7, of a note PC according to a first embodiment of the present invention. In FIG. 5 through FIG. 7, parts that are the same as the parts shown in FIG. 2 through FIG. 4 are given the same reference numerals.

FIG. 5 is an illustrative cross-sectional view of an enclosure of a note PC as an example of an information technology equipment according to a first embodiment of the present invention. In FIG. 5, a state where a memory module cover 32 is removed from an enclosure 38 is shown. Similar to the structure shown in FIG. 2 through FIG. 4, a printed circuit board assembly is incorporated in the enclosure 38. The printed circuit board assembly has a printed circuit board 16 and circuit parts mounted on the printed circuit board 16 and connectors 14A and 14B arranged in parallel and mounted on the printed circuit board 16. Memory modules 10A and 10B are connected to the connectors 14A and 14B, respectively. An opening 38a is formed in the enclosure 38 under the memory modules 10A and 10B, and a memory module cover 32 is attached to the enclosure 38 so as to close the opening part 38a.

In order to protect the memory modules 10A and 10B, insulation films 17A and 17B are provided to extend between the memory modules 10A and 10B and the memory module cover 32. One side portion of the insulated film 17A is bent by 90 degrees, and is applied to a side surface of the memory module 10A via an electromagnetic wave absorption sheet 34A. More specifically, the electromagnetic wave absorption sheet 34A is applied by a pressure sensitive adhesive to an inner side of the one side portion of the insulation film 17A bent by 90 degrees. A pressure sensitive adhesive is also applied to a front surface of the electromagnetic wave absorption sheet 34A so that the electromagnetic wave absorption sheet 34A is applied to the side surface of the connector 14A. Accordingly, the insulation film 17A is applied to the side surface of the connector 14A via the electromagnetic wave absorption sheet 34A, and most part of the entire side surface of the connector 14A is covered by the electromagnetic wave absorption sheet 34A. Similarly, the insulation film 17B is applied to the side surface of the connector 14B via an electromagnetic wave absorption sheet 34B, and most part of the entire side surface of the connector 14B is covered by the electromagnetic wave absorption sheet 34B.

The electromagnetic wave absorption sheets 34A and 34B are, for example, a sheet material formed by sandwiching powders made of a high-permeability material between two flexible sheets, which can efficiently suppress high-frequency electromagnetic waves. Thus, the electromagnetic wave absorption sheets 34A and 34B have an action to suppress electromagnetic wave between the connectors 10A and 10B.

Although the electromagnetic wave absorption sheets 34A and 34B are provided to both the connectors 10A and 10B, respectively, in the present embodiment, the electromagnetic wave suppressing effect can be obtained by merely providing the electromagnetic wave absorption sheet to one of the connectors 10A and 10B. For example, if a component part made by the insulation film having the electromagnetic wave absorption sheet being applied thereto is used in common as the electromagnetic wave absorption sheets 34A and 34B, a number of parts is reduced and rise in the assembly cost can be suppressed. On the other hand, by preparing an insulation film having the electromagnetic wave absorption sheet applied thereto and an insulation film without applying an insulation film, rise in the parts cost can be suppressed by a cost corresponding to one sheet of the electromagnetic wave absorption sheet.

In the present embodiment, the electromagnetic wave shielding structure is provided also to a peripheral part of the memory module cover 32. An electrically conductive metal plating is applied to or an electrically conductive material such as a metal plate or a metal foil is applied to the backside of the memory module cover 32 so as to obtain an electromagnetic wave shielding effect. That is, when the memory module cover 32 is attached to the opening part 38a of the enclosure 38, the electromagnetic wave shielding effect can be obtained by taking electric conduction between the memory module cover 32 and a grounded part of the enclosure 38. Although it is preferable to take electric conduction along an entire circumference of the memory module cover 32, it is difficult to take electric conduction along an entire circumference of the memory module cover 32. Thus, in the present embodiment, electrically conductive portions are provided with a predetermined interval.

The metal plate 39 provided inside the enclosure 38 is a grounded portion which is set at a ground potential. Thus, in the present embodiment, small through holes 38c are provided along the periphery of the opening part 38a of the enclosure 38 and protruding parts 39a formed by bending the metal plate 39 are caused to protrude through the through holes 38c. The through holes 38c are formed in a portion covered by the memory module cover 32 when the opening part 38a is closed by the memory module cover 32. Accordingly, in the state where the opening part 38a is closed by the memory module cover 32, the protruding parts 39a protruding from the through holes 38c are brought into contact with the electrically conductive material on the backside of the memory module cover 32, thereby surely making electric connection between the memory module cover 32 and the metal plate 39 of the enclosure 38. Since the metal plate 39 is set at a ground potential, the memory module cover 32 is also set at the ground potential, thereby obtaining an electromagnetic wave shielding effect.

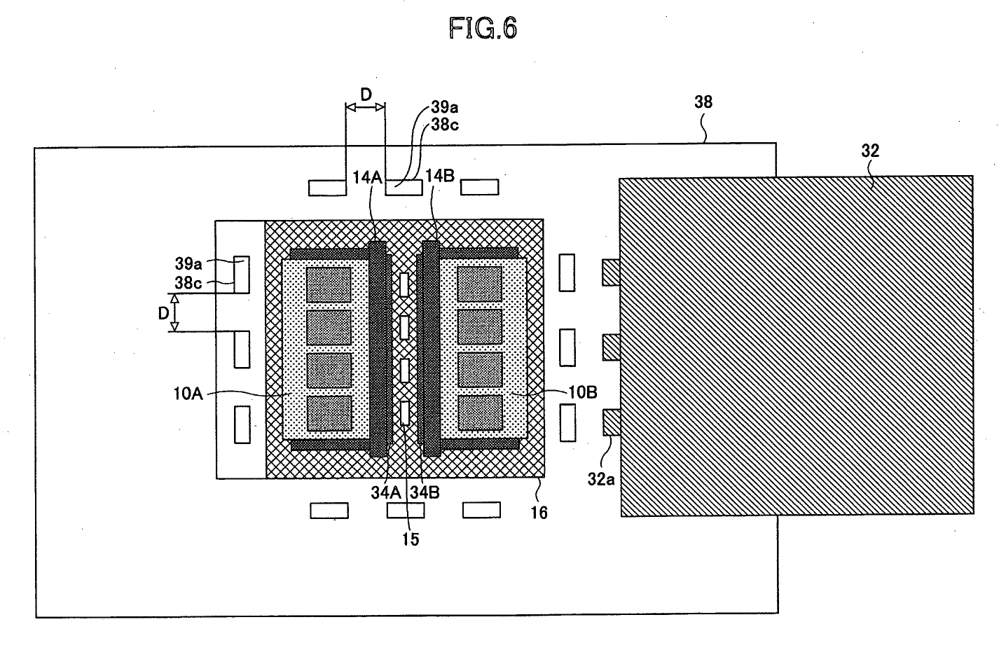

Here, in the present embodiment, the interval (indicated by D in FIG. 6) of the protruding parts 39a of the metal plate 39 is about 30 mm or less. If the operation frequency of the memory modules 10A and 10B, that is, the system bus clock of the memory modules 10A and 10B is set to 133 MHz, the signal wavelength λ at 1 GHz (≈133 MHz×8) is 300 mm. The interval of the protruding parts 38a is set to 1/10 of the wavelength λ=300 mm so that harmonic wave corresponding 10 times the wavelength λ can be shielded. Electromagnetic wave can be shielded effectively by electrically connecting the memory module cover 32 and the metal plate 39 with an interval equal to or smaller than a wavelength of a tenth harmonic wave of electronic wave which may be generated.

FIG. 6 is an illustrative plan view viewed from a bottom side of the enclosure shown in FIG. 5, and a state where the memory module cover 32 is removed is shown. It should be noted that a state where the insulation films 17A and 17B are removed is shown in FIG. 6 so as to show the interior. As shown in FIG. 6, in the present embodiment, the memory module cover 32 for closing the opening part 38a of the enclosure 38 is configured to be attached to the opening part 38a while being moved perpendicular to the extending direction of the connectors 14A and 14B arranged parallel to each other on the printed circuit board 16. That is, the protruding parts 32a of the memory module cover 32 are formed on one side parallel to the extending direction of the connectors 14A and 14B, and a direction of insertion of the protruding parts 32a is coincident with a direction perpendicular to the extending direction of the connectors 14A and 14B.

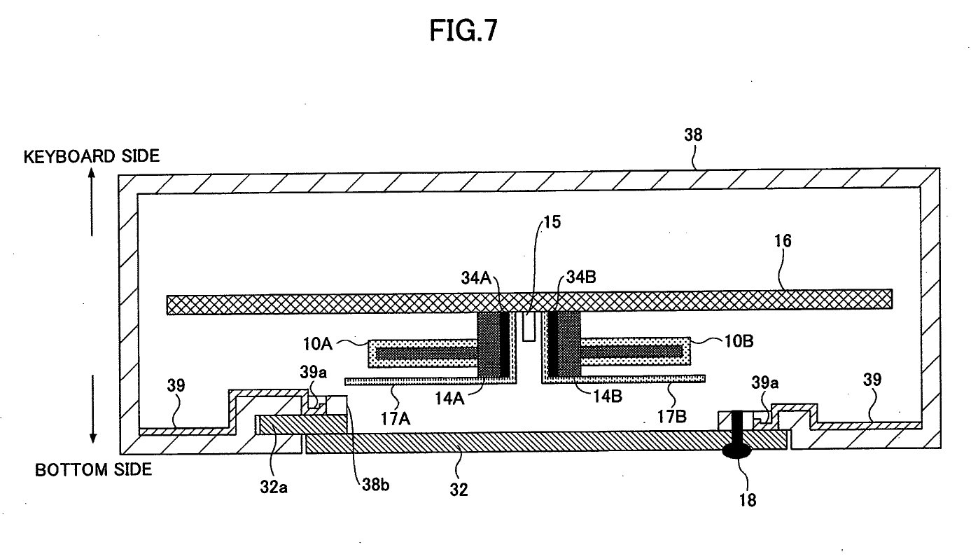

FIG. 7 is an illustrative cross-sectional view showing a state where the memory module cover 32 is attached to the opening 38a. The protruding parts 32a of the memory module cover 32 are inserted into the engaging parts 38b of the enclosure 38, and the memory module cover 32 is attached to the opening part 38a and fixed to the enclosure 38 by screws 18. As shown in FIG. 7, in the state where the memory module cover 32 is attached to the opening part 38a, the protruding parts 39a of the metal plate 39 protruding through the through holes 38c are brought into contact with the backside (electrically conductive material) of the memory module cover 32, thereby achieving electric conduction at the contacting portions. Accordingly, the memory module cover 32 is at the same ground potential with the metal plate 39 which is a ground potential portion of the enclosure 38. Thereby, electromagnetic waves generated by the operations of the memory modules 10A and 10B are shielded, and an amount of leakage of the electromagnetic waves through the opening part 38a is suppressed effectively.

Here, with the connection structure of the memory modules according to the present embodiment, in order to reduce a height from the printed circuit board 16, the memory modules 10A and 10B are connected at positions close to the surface of the printed circuit board 16 as much as possible. Therefore, electronic circuit parts cannot be mounted between the memory modules 10A and 10B and the printed circuit board 16. However, it is necessary to provide a termination circuit of the connector terminals near the connectors 14A and 14B. The termination circuit includes an electronic circuit part 15 such as a decoupling capacitor, and a distance to the connector must be as small as possible.

Thus, in the present embodiment, the termination circuit including the electronic circuit part 15 is mounted on the printed circuit board 16 between the connectors 14A and 14B arranged parallel to each other. The portion between the connectors 14A and 14B is a portion where signal lines are gathered from both sides and thus a portion where especially a large amount of electromagnetic waves are generated. Although the electromagnetic waves can be shielded by providing a ground potential portion by applying an electrically conductive material such as a metal foil to the portion between the connectors 14A and 14B, such as an electrically conductive material cannot be applied to the printed circuit board 16 between the connectors 14A and 14B if the electronic circuit part 15 is mounted between the connectors 14A and 14B as in the present embodiment. However, in the present invention, since the electric connection is effectively achieved in the peripheral portion of the memory module cover 32 as mentioned above, electromagnetic waves generated at the portion between the connectors 14A and 14B can be shielded. That is, according to the present embodiment, while reducing the height of the connection structure of the memory modules 10A and 10B, unnecessary electromagnetic waves generated by operations of the memory modules 10A and 10B can be effectively shielded, thereby preventing the electromagnetic waves from leaking outside.

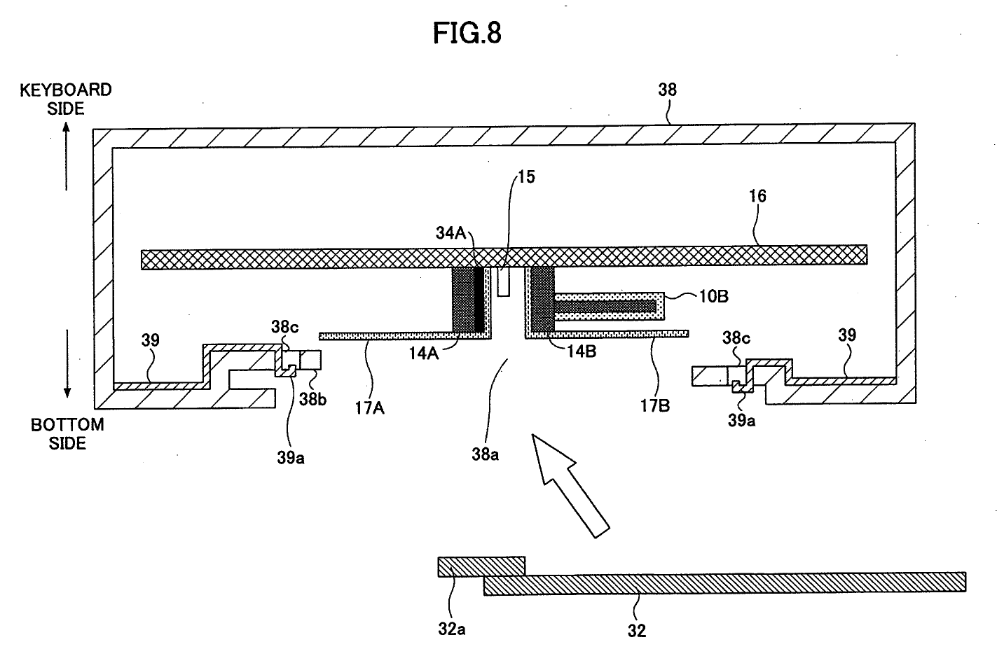

A description will now be given, with reference to FIG. 8 through FIG. 10, of a note PC according to a second embodiment of the present invention. In FIG. 8 through FIG. 10, parts that are the same as the parts of the above-mentioned first embodiment are given the same reference numerals, and descriptions thereof will be omitted.

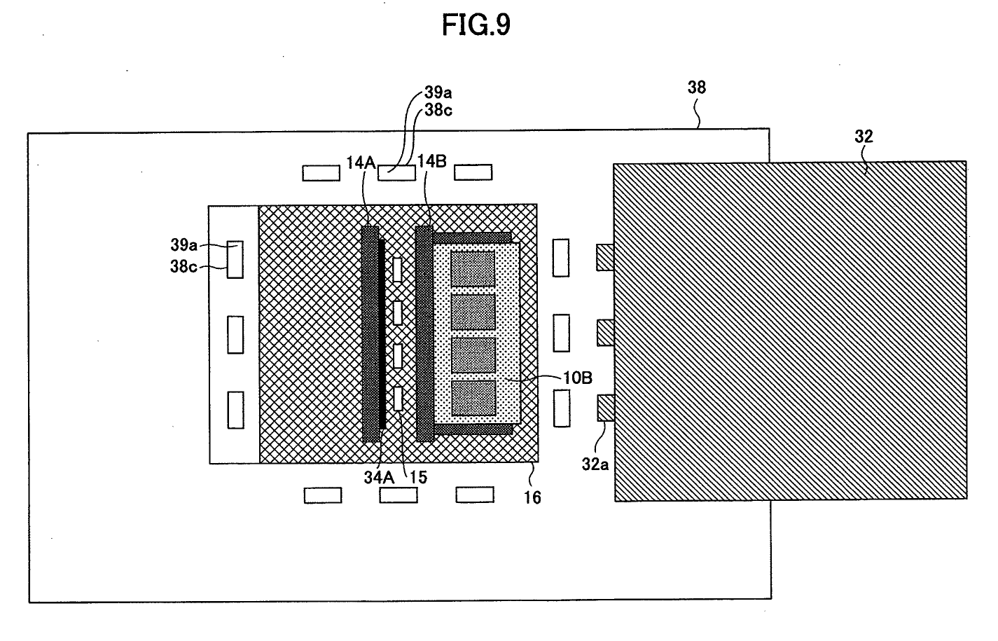

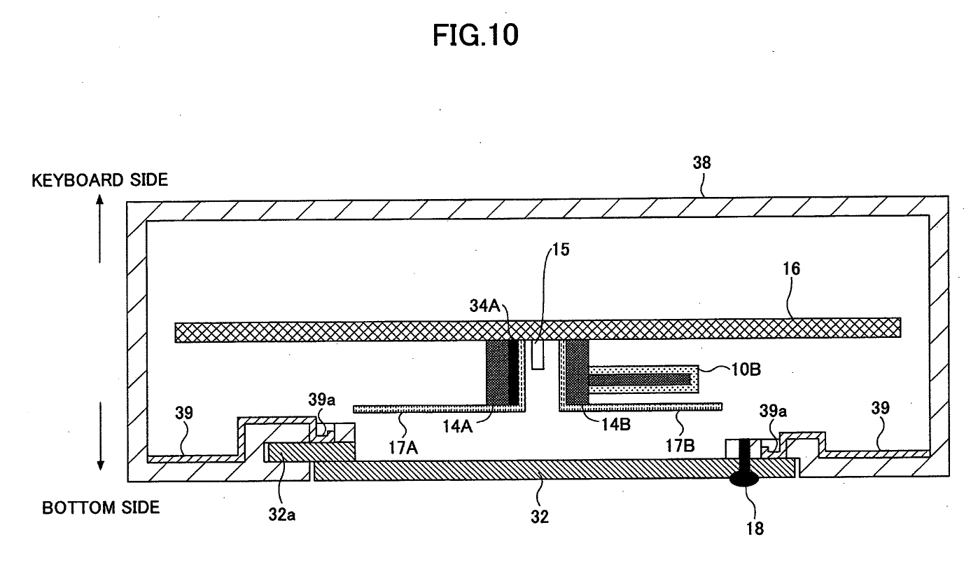

FIG. 8 is an illustrative cross-sectional view of an enclosure of a note PC as an example of an information technology equipment according to a second embodiment of the present invention. In FIG. 8, a state where a memory module cover 32 is removed from an enclosure 38 is shown. FIG. 9 is an illustrative plan view of the enclosure 38 viewed from a bottom side thereof, and a state where the memory module cover 32 is removed is shown. FIG. 10 is an illustrative cross-sectional view showing a state where the memory module cover 32 is attached to an opening part 38a of the enclosure 38.

In the present embodiment, although the memory module 10B is connected to the connector 14B, the memory module 10A is not connected to the connector 14A, and the connector 14A is maintained vacant (unconnected). That is, the connector 14 is a connector for memory extension, and a user can connect the memory module 10A afterwards if needed. Therefore, if memory extension is not needed, the note PC can be operated with only the memory module 10B as in the present embodiment.

Although electromagnetic wave absorption sheet 34A is applied to the vacant connector 14A in the present embodiment, the electromagnetic wave absorption sheet is not provided to the connector 14B. In order to suppress the electromagnetic waves between the connectors 14A and 14B, a sufficient effect can be obtained with the electromagnetic wave absorption sheet 34A alone. Of course, if the electromagnetic wave absorption sheet is applied to both the connectors 14A and 14B, the electromagnetic waves can be shielded more surely. Additionally, the electromagnetic wave absorption sheet may not be applied to the vacant connector 14A but applied to only the connector 14B to which the memory module 10B is connected.

As mentioned above, according to each embodiment mentioned above, electromagnetic waves generated at the terminals of the vacant connector can be reduced by applying the electromagnetic wave absorption sheet to the connector to which the memory module is connected and efficiently connecting the memory module cover to the ground potential part of the enclosure. Thus, an information technology equipment which can clear the limited specified by the standard of a regulation regarding electromagnetic interference can be achieved while reducing a cost needed for taking countermeasures for reducing electromagnetic waves.

For example, when the above-mentioned embodiment is applied to a note PC mounting the Pentium-M945GM chip set (Pentium is registered trademark.), a noise level when a single memory module SO-DIMM is connected can be reduced by 4 dB to 5 dB. Conventionally, an electromagnetic wave absorption sheet is applied to an entire back surface of a memory module cover and the memory module cover is electrically connected to a ground portion of an enclosure using an electrically conductive gasket. Thus, in the conventional method, a large amount of expensive electromagnetic wave absorption sheet and expensive electrically conductive gasket is used. On the other hand, by using the shielding structure according to the present invention, a sufficient electromagnetic wave shielding can be achieve efficiently while reducing a cost by merely using an electromagnetic wave absorption sheet of a size to cover only the side surface of the connector.

For example, if a low-height connector having a connector pin size of 60 mm×4 mm is used, the size of the electromagnetic wave absorption sheet to be applied to the side surface of the connector is 60 mm×4 mm and its area is 240 mm². If the electromagnetic wave absorption sheet is applied to each of the two connectors as in the first embodiment, the area is 240×2=480 mm².

On the other hand, in the case where the electromagnetic wave absorption sheet is applied to an entire back surface of a memory module cover as in the conventional method, if the size of the memory module cover is 78 mm×88 mm, the necessary size of the electromagnetic absorption sheet to be applied to the back surface of the memory module cover is an area of 78 mm×88 mm=6864 mm². In addition, generally, an electromagnetic wave absorption sheet of a size that can cover an area directly under the memory module is applied doubly. Thus, two sheets of an electromagnetic wave absorption sheet corresponding to the size of the memory module 60 mm×30 mm=1800 mm² are needed. That is, an area of the electromagnetic wave absorption sheet necessary for the conventional structure is 6864+1800×2=10,404 mm².

As mentioned above, if the area of the electromagnetic wave absorption sheet required for the shielding structure according to the first embodiment of the present invention is 480 mm², the area of the electromagnetic wave absorption sheet required for the conventional shielding structure is 10,404 mm², which means that the conventional shielding structure requires the electromagnetic wave absorption sheet of the size about 22 times the size of the electromagnetic wave absorption sheet required by the shielding structure according to the first embodiment of the present invention. In other words, by adopting the shielding structure according to the first embodiment of the present invention, the size of the electromagnetic wave sheet necessary for the shielding structure can be reduced to 1/22. Since the electromagnetic wave absorption sheet is a relatively expensive material, the cost spent on the electromagnetic wave absorption sheet can be greatly reduced by adopting the shielding structure according to the first embodiment of the present invention. For example, if the unit cost of an electromagnetic wave absorption sheet is 4.0 yen/cm², the electromagnetic wave absorption sheet corresponding to (104.04-4.8)×4.0≈400 yen can be reduced. If the electromagnetic wave absorption sheet is applied only to one of the connectors as in the second embodiment of the present invention, the size of the electromagnetic wave absorption sheet used can be further reduced.

The present invention is not limited to the specifically disclosed embodiments, and variations and modifications may be made without departing from the scope of the present invention.

The present invention is based on Japanese priority application No. 2007-009392 filed Jan. 18, 2007, the entire contents of which is hereby incorporated herein by reference.

What is claimed is:

1. A printed circuit board assembly configured and arranged so that memory modules are mounted thereto, the printed circuit board assembly comprising:
a printed circuit board;
at least two connectors mounted on the printed circuit board, the connectors being configured so that the memory modules are connected thereto;
an electromagnetic wave absorption sheet provided to at least one of the connectors,
wherein the electromagnetic wave absorption sheet is attached so as to cover a side surface of said one connector facing a side surface of the other connector.

2. The printed circuit board assembly as claimed in claim 1, wherein said electronic wave absorption sheet is provided to each of said connectors.

3. The printed circuit board assembly as claimed in claim 1, wherein an insulation film is applied to a surface of said electromagnetic wave absorption sheet, and the insulation film is applied to said side surface of said one connector via said electromagnetic wave absorption sheet.

4. The printed circuit board assembly as claimed in claim 3, wherein said insulation film has a portion bent from a portion applied to said side surface of said one connector and extending parallel to said printed circuit board, and said insulation film is arranged so as to cover one of said memory modules when said one of said memory modules is connected to said one connector.

5. The printed circuit board assembly as claimed in claim 1, wherein said electromagnetic wave absorption sheet is applied to said side surface of said one connector by a pressure sensitive adhesive.

6. The printed circuit board assembly as claimed in claim 1, wherein an electronic circuit part is mounted on said printed circuit board between said connectors mounted in parallel.

7. The printed circuit board assembly as claimed in claim 6, wherein said electronic circuit part is a part of a voltage stabilizer circuit connected to a power supply line for supplying power to said memory modules.

8. An enclosure of information technology equipment configured so that a printed circuit assembly is incorporated therein, the printed circuit assembly being configured so that memory modules are mounted opposite and parallel to each other, the enclosure of information technology equipment comprising:
an opening part provided on an enclosure wall at a position opposite to said memory modules;
a memory module cover for closing the opening part; and
a metal plate provided to cover an inner surface of said enclosure wall on which said opening part is provided, the metal plate being at a ground potential,
wherein a conductive material is provided on an inner surface of said memory module cover, and a portion of said metal plate is formed as a protruding part so that the protruding part is in contact with the conductive material in a vicinity of said opening part.

9. The enclosure of information technology equipment as claimed in claim 8, wherein said protruding part of said metal plate is provided at a plurality of positions along a periphery of said opening part, and an interval of said protruding parts is determined based on an operation frequency of said memory modules.

10. The enclosure of information technology equipment as claimed in claim 9, wherein the interval of said protruding parts is 1/10 of a wavelength of tenth harmonic wave of a signal operation frequency at a signal line of said memory modules.

11. The enclosure of information technology equipment as claimed in claim 8, wherein said protruding part extends through a through hole formed in a periphery of said opening part so as to contact with said conductive material of said memory module cover.

12. An information technology equipment having a changeable memory capacity, comprising:
the printed circuit board assembly as claimed in claim 1; and
the enclosure of information technology equipment as claimed in claim 8,
wherein said printed circuit board assembly is incorporated into said enclosure of information technology equipment.
